(19) United States
(12) Patent Application Publication
(10) Pub. No.: US 2006/0125526 A1
(43) Pub. Date: Jun. 15, 2006

(54) Differential analog logic circuit with symmetric inputs and output

(76) Inventor: Hooman Darabi, Irvine, CA (US)

Correspondence Address: CHRISTIE, PARKER & HALE, LLP, PO BOX 7068, PASADENA, CA, 91109-7068, US

(21) Appl. No.: 11/055,873

(22) Filed: Feb. 11, 2005

Related U.S. Application Data
(60) Provisional application No. 60/635,750, filed on Dec. 14, 2004.

(51) Int. Cl. H03K 19/094

(52) U.S. Cl. 326/112

(57) ABSTRACT

A logic circuit incorporates symmetric inputs and/or a symmetric output. The logic circuit may include symmetric input circuits such that each input signal may be processed by a circuit that provides substantially identical rise times and fall times. The input circuits may provide symmetric loading of the input signals by providing a substantially identical circuit configuration for each input signal. The logic circuit may include a symmetric output circuit such that the output signals generated by the output circuit may have substantially identical rise times and fall times. Each leg of a differential output circuit may incorporate a substantially identical circuit configuration.

### CROSS-REFERENCE TO RELATED APPLICATION(S)

This application claims the benefit of U.S. Provisional Patent Application No. 60/635,750, filed Dec. 14, 2004, the disclosure of which is hereby incorporated by reference herein.

### TECHNICAL FIELD

This application relates to logic circuits and, more specifically, to a differential logic circuit with symmetric inputs and output.

### BACKGROUND

Conventional logic circuits perform logical operations such as AND, NAND, OR, NOR and XOR. Traditionally, logic circuits may be constructed of several transistors and other circuit components such as resistors, capacitors, etc. In practice, the components used to implement the logic function may adversely affect the input and output signals for the logic circuit.

In some conventional logic circuits different circuit configurations may be used to generate the rising and falling edges of a signal. For example, one type of transistor (e.g., PMOS) is used to generate the rising edge of a signal and another type of transistor (e.g., NMOS) is used to generate the falling edge of the signal. Since these different types of transistors generally have different speed characteristics (e.g., NMOS is faster), the resulting rise and fall times may be different. As a result, the symmetry of the signal may be adversely affected.

In addition, some conventional logic circuits may impart different loading on different signals. For example, a different number of transistors may connect to each input or output lead. In addition, different signals paths having different characteristics may be coupled to different input or output leads. As a result of such properties of the circuit implementations, the symmetry of the input and/or output signals may be adversely affected.

At some speeds of operation (e.g., relatively high speeds), any asymmetry in a signal may adversely affect the performance of the system within which the logic circuits are incorporated. Accordingly, a need exists for logic circuits with improved performance characteristics.

### SUMMARY

The invention relates to a logic circuit with symmetric inputs and a symmetric output. For convenience, an embodiment of a system constructed or a method practiced according to the invention will be referred to herein simply as an “embodiment.”

In one aspect of the invention a logic circuit comprises a plurality of inputs and at least one output. For example, the logic circuit may provide a logical operation such as AND, NAND, OR, NOR, XOR, etc.

In one aspect of the invention the logic circuit includes symmetric input circuits. Through the use of symmetric circuits, the logic circuit may substantially maintain symmetry of signals processed by the input circuits. Here, symmetry may relate to symmetry in a given input signal and/or it may relate to symmetry between the two input signals.

In some embodiments each input signal may be processed by a circuit that has substantially identical rise times and fall times. This may be accomplished, for example, by constructing an input circuit using the same type of gates. For example, in some embodiments all of the transistors in an input circuit are NMOS transistors. In this way, the input circuit may substantially maintain the symmetrical transitional characteristics of the input signal.

In some embodiments the input circuits may provide symmetric loading of the input signals by providing a substantially identical circuit configuration for each input signal. In this way, the input circuits may substantially maintain the symmetry between input signals.

For example, substantially identical signals paths may be provided for each input signal through each input circuit. Here, each signal path may incorporate substantially identical components as the other signal path. As a result, each input signal may drive the same number of transistors in the input circuit.

In one aspect of the invention the logic circuit includes a symmetric output circuit. Here, the symmetry may relate to symmetry in the signal generated by a single leg (e.g., the positive or negative terminal) of the differential output circuit and/or it may relate to symmetry between the two legs of the output.

In some embodiments the output signals generated by the output circuit may have substantially identical rise times and fall times. This may be accomplished by using the same type of gates to generate the rising and falling transitions of the output signal. For example, in some embodiments all of the transistors in the output circuit are NMOS transistors. In this way, the output circuit may generate output signals that have substantially symmetrical transitional characteristics.

In some embodiments each leg (e.g., the positive or negative terminal) of the differential output circuit may incorporate a substantially identical circuit configuration. As a result each leg of the differential output circuit may have substantially identical loading. In this way, the output circuit may substantially maintain the symmetry of the signals output on each leg of the differential output.

Here, substantially identical signal paths may be provided for each leg of the output signal through the output circuit. For example, each signal path may incorporate substantially identical components and connections as the other signal path. As a result, each leg of the differential output may connect to the same number of transistors. This may be accomplished through the use of “dummy” circuits. In addition, in some embodiments the same number of transistors may be turned on in each leg of the output circuit for similar output states of the logic device.

### BRIEF DESCRIPTION OF THE DRAWINGS

These and other features, aspects and advantages of the present invention will be more fully understood when considered with respect to the following detailed description, appended claims and accompanying drawings, wherein:

FIG. 1 is a simplified block diagram of one embodiment of a logic circuit constructed in accordance with the invention;

FIG. 2 is a simplified flowchart of one embodiment of operations that may be performed by a logic circuit in accordance with the invention; and

FIG. 3 is a simplified schematic diagram of one embodiment of a logic circuit constructed in accordance with the invention.

In accordance with common practice the various features illustrated in the drawings may not be drawn to scale. Accordingly, the dimensions of the various features may be arbitrarily expanded or reduced for clarity. In addition, some of the drawings may be simplified for clarity. Thus, the drawings may not depict all of the components of a given apparatus or method. Finally, like reference numerals denote like features throughout the specification and figures.

### DETAILED DESCRIPTION

The invention is described below, with reference to detailed illustrative embodiments. It will be apparent that the invention may be embodied in a wide variety of forms, some of which may be quite different from those of the disclosed embodiments. Consequently, the specific structural and functional details disclosed herein are merely representative and do not limit the scope of the invention.

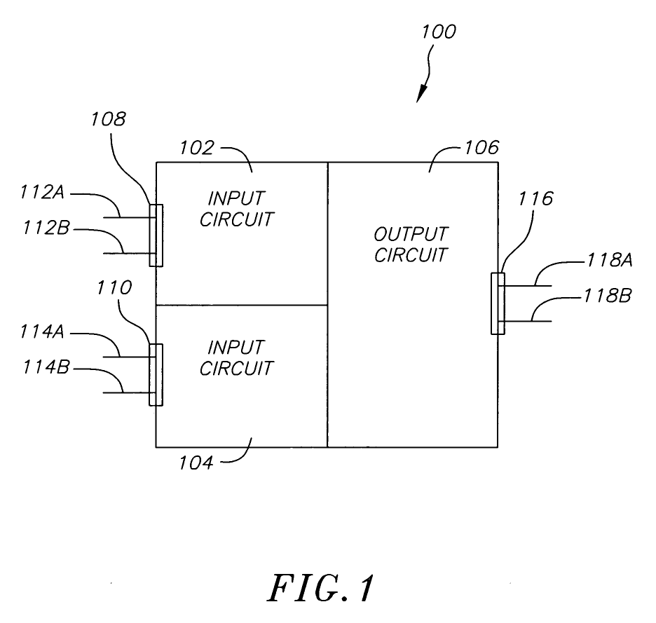

FIG. 1 is a simplified block diagram of one embodiment of a logic circuit 100. The logic circuit includes a plurality of input circuits 102 and 104 and an output circuit 106. Each input circuit includes a differential pair input terminal 108 and 110 that connects to differential input signal leads 112A-B and 114A-B, respectively. The output circuit includes a terminal 116 that connects to differential output signal leads 118A-B. In practice, the input and output circuits may share one or more components and/or connections. In addition, a given logic circuit may include additional input circuits and/or output circuits.

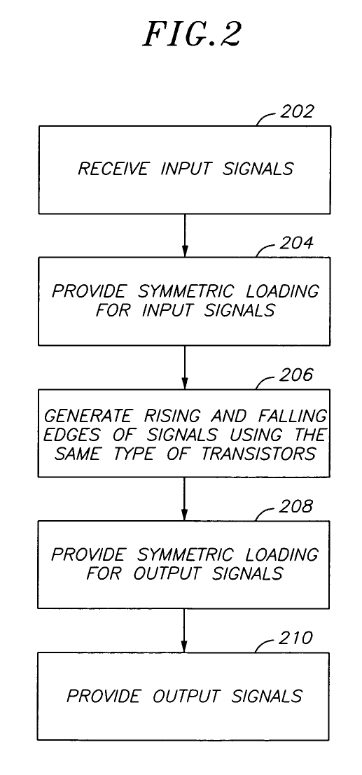

The logic circuit may be implemented to maintain symmetric of the input signals and/or provide symmetric output signals. One embodiment of operations that may be performed by the logic circuit will be described in conjunction with the flowchart of FIG. 2. Initially, as represented by block 202, the logic circuit 100 receives input signals at the input terminals 108 and 110.

As represented by block 204, the circuit 100 may provide symmetric loading for the input signals on input leads 112A-B and 114A-B. In some embodiments each input circuit 102 and 104 is constructed using the same circuit configuration. For example, each input circuit may incorporate the same number of components. In addition, the components (e.g., transistors, etc.) used in each corresponding portion of the input circuits may have substantially identical characteristics (e.g., size, etc.). Also, each input circuit may incorporate substantially identical interconnections between components. It follows then, that the signal paths for each input signal through each input circuit may be substantially similar.

As a result, the input circuit 102 may impart substantially the same loading on the input signal received at terminal 108 as the input circuit 104 imparts on the input signal received at terminal 110. In this way, the input circuits may avoid imparting asymmetric characteristics on the input signals. In other words, if the input signals received at terminals 108 and 110 have substantially identical characteristics (e.g., duty cycle, rise times and fall times), the input circuits may generate corresponding signals having substantially identical characteristics.

As represented by block 206, the circuit 100 may generate rising and falling edges of signals using the same type of transistors. Here, in some embodiments an input circuit may be constructed using the same type of components. For example, all of the transistors in input circuit 102 may be NMOS transistors. Alternatively, all of the transistors in input circuit 102 may be PMOS transistors. As a result, the input circuit may impart substantially identical rise times and fall times on the input signals. In other words, if an input signal (e.g., the signal on lead 112A) has substantially identical rise times and fall times, the input circuit may generate a corresponding signal having substantially identical rise times and fall times. This is in contrast with some conventional circuits where asymmetry may be imparted on the resulting signal due to the use of different types of transistors (e.g., PMOS and NMOS) for generating the rising and falling edges of the signal.

Similarly, in some embodiments the output circuit 106 may be constructed using the same type of components. For example, all of the transistors in output circuit 106 may be NMOS transistors. Alternatively, all of the transistors may be PMOS transistors. As a result, the output circuit may impart substantially identical rise times and fall times on the signals it processes to generate the output signal. In other words, if a signal being processed by the output circuit has substantially identical rise times and fall times, the output circuit may generate an output signal (e.g., at lead 118A) having substantially identical rise times and fall times.

As represented by block 208, the circuit 100 may provide symmetric loading for the output signals. In some embodiments each leg (e.g., the circuit components that connect to output signal lead 118A or the circuit components that connect to output signal lead 118B) of the differential output circuit may incorporate a substantially identical circuit configuration. For example, output signal lead 118A may connect to the same number of transistors as the output signal lead 118B. In addition, each leg may incorporate the same number of components and the components (e.g., transistors, etc.) used in each leg may have substantially identical characteristics (e.g., size, etc.). Also, each leg may incorporate substantially identical interconnections between components. It follows then, that the signal paths through each leg that generate each output signal may be substantially identical.

As a result each leg of the differential output circuit 106 may have substantially identical loading. In this way, the output circuit 106 may substantially maintain the symmetry of the signals output on each leg of the differential output. In other words, if the signals processed by each leg of the output circuit have substantially identical characteristics (e.g., duty cycle, transition times, rise times and fall times), the output circuit may generate output signals (block 210) having substantially identical characteristics.

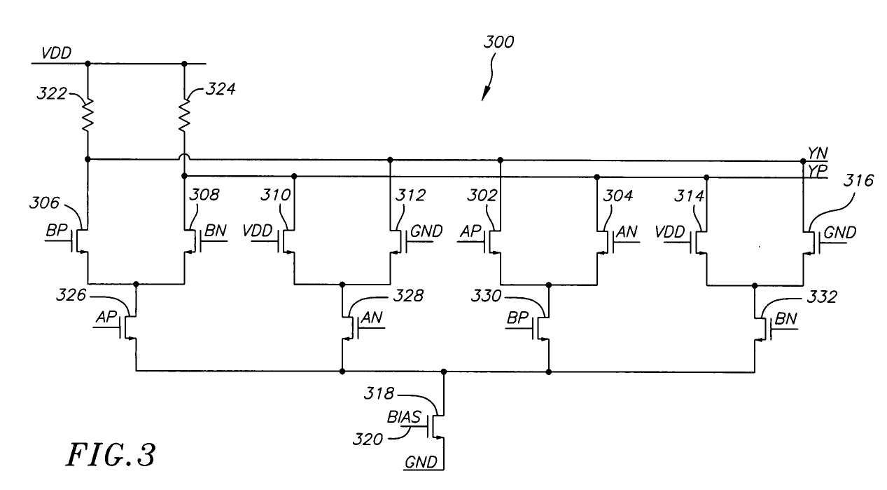

FIG. 3 is a simplified schematic diagram of one embodiment of a differential analog AND circuit 300 constructed in accordance with the invention. One set of differential inputs to the AND circuit 300 is designated AP and AN. Another set of differential inputs to the AND circuit 300 is designated BP and BN.

The differential output of the AND circuit is designated YP and YN. Each differential output lead connects to a load (e.g., resistors 322 and 324) that in turn connects to a supply voltage VDD.

The AND circuit 300 includes four differential transistor pairs. The differential input AP, AN drives a differential transistor pair comprising transistors 302 and 304. The differential input BP, BN drives a differential transistor pair comprising transistors 306 and 308.

Transistors 310 and 312 comprise a first “dummy” differential pair and transistors 314 and 316 comprise a second “dummy” differential pair. The inputs to the “dummy” differential pairs connect to the supply voltage VDD and ground GND. Thus, the transistors 310 and 314 are always biased to be on and the transistors 312 and 316 are never biased on.

A current source (e.g., transistor 318) provides the sink current for the differential pairs. In this example, a control signal (e.g., bias signal 320) controls the magnitude of the current flowing though the current source.

Four transistors 326, 328, 330 and 332 further control the flow of current between the differential pairs and the current source. Input AP controls transistor 326. Input AN controls transistor 328. Input BP controls transistor 330. Input BN controls transistor 332.

The circuit 300 performs the AND function as follows. When both AP and BP are high (input state “1,1”), current will not flow through the dummy differential pairs since transistors 328 and 332 will be biased off. However, current will flow to the other differential pairs. Here, transistors 302 and 306 will be biased on and transistors 304 and 308 will be biased off. As a result, no current will flow through any of the transistors connected to YP and YP will be driven high by the resistor 324. In addition, YN will be driven low by current flow through transistors 302 and 308.

When either AP or BP is low, at least one of the dummy differential pairs will be activated. For example, when AP is low, transistor 328 will be biased on and current will flow through transistors 310 and 328. As a result, output YP will be driven low. Similarly, when BP is low, transistor 332 will be biased on and current will flow through transistors 314 and 332. As a result, output YP will be driven low.

The configuration of the differential pairs serves to ensure that substantially equivalent current flows are associated with each state of the AND logic circuit. Namely, for each low output state for YP (AP, BP input states “0,0” or “0,1” or “1,0”), current will only flow though two of the four differential pairs. For example, for input state “0,0” current will only flow through the two “dummy” differential pairs (transistors 326 and 330 will be biased off). For input state “0,1” current will only flow through the two differential pairs in the middle of FIG. 3 (transistors 326 and 332 will be biased off). For input state “1,0” current will only flow through the left most and right most differential pairs of FIG. 3 (transistors 328 and 330 will be biased off).

From the above, it may be appreciated that the AND circuit 300 incorporates symmetric input circuits. First, each input circuit imparts substantially identical loading on each input signal (AP, AN, BP or BN) . Second, the components of an input circuit may generate signals with substantially identical rise times and fall times.

Regarding the loading, each input signal connects to the same number of transistors. For example, in FIG. 3 each input signal connects to two transistors.

In addition, each input signal drives a substantially identical circuit configuration. For example, input signal AP drives the gate of transistor 326 which connects to the current source. In addition, input signal AP drives the gate of a differential pair transistor 302 which connects through a transistor 330 to the current source. Similarly, input signal BP drives the gate of transistor 330 which connects to the current source. In addition, input signal BP drives the gate of a differential pair transistor 306 which connects through a transistor 326 to the current source. Input signals AN and BN also drive similar circuits.

Here, all of the corresponding transistors may be substantially identical. For example, all of the differential pair transistors 306-316 may have substantially identical characteristics (e.g., size, operating parameters, etc.). In addition, all of the transistors 326-332 may have substantially identical characteristics.

Regarding the rise and fall times, all of the transistors in the AND circuit 300 are of the same type (e.g., NMOS). Accordingly, each of these transistors may generate signals having substantially identical rise times and fall times. For example, assuming input signal AP has substantially identical rise and fall times, a signal generated by transistor 326 or a signal generated by transistor 302 may have substantially identical rise and fall times.

From the above, it also may be appreciated that the AND circuit 300 incorporates a symmetric output circuit. First, the output circuit imparts substantially identical loading on each output signal (YP or YN). Second, the components of the output circuit may generate signals with substantially identical rise times and fall times.

Regarding the loading, the same number (and type) of transistors connect to each output YP or YN. In this example, four transistors (one from each of the differential pairs) connect to each output YP or YN.

Here, the incorporation of the “dummy” differentials pairs provides additional transistor loading for the output signals YP and YN while maintaining the proper AND function. As discussed above, a portion of the AND function is provided by the transistors 328 and 332. Namely, assuring that YP is low when either AP or BP is low. While the same logic function may be provided using a circuit where the outputs of transistors 328 and 332 connect directly to the output signal YP, this alternative circuit would result in an asymmetric configuration where two transistors are connected to YN and four transistors are connected to YP.

The teachings of the inventions may be incorporated into a variety of circuits. For example, as mentioned above logic circuits such as an AND circuit, a NAND circuit (e.g., by adding an inverter to the embodiment of FIG. 3), an OR gate (e.g., by switching the inputs in the embodiment of FIG. 3), a NOR gate, an XOR gate, etc., may be constructed in accordance with the teachings hearing. Moreover, such logic circuits may be incorporated into other, more complex circuits.

Different embodiments of the invention may be implemented using a variety of processes. For example, in some embodiments CMOS processes may be used to implement a circuit. However, it should be understood that other processes may be used to implement a circuit.

The components and functions described herein may be connected/coupled in many different ways. The manner in which this is done may depend, in part, on whether the components are separated from the other components. In some embodiments some of the connections represented by the lead lines in the drawings may be in an integrated circuit or on a circuit board.

The signals discussed herein may take several forms. For example, in some embodiments a signal may be an electrical signal transmitted over a wire. A signal may comprise more than one signal. For example, a signal may consist of a series of signals. Also, a differential signal comprises two complementary signals or some other combination of signals. Thus, a group of signals may be collectively referred to herein as a signal.

The components and functions described herein may be connected/coupled directly or indirectly. Thus, in some embodiments there may or may not be intervening devices (e.g., buffers) between connected/coupled components.

In summary, the invention described herein generally relates to an improved logic circuit. While certain exemplary embodiments have been described above in detail and shown in the accompanying drawings, it is to be understood that such embodiments are merely illustrative of and not restrictive of the broad invention. In particular, it should be recognized that the teachings of the invention apply to a wide variety of systems and processes. It will thus be recognized that various modifications may be made to the illustrated and other embodiments of the invention described above, without departing from the broad inventive scope thereof. In view of the above it will be understood that the invention is not limited to the particular embodiments or arrangements disclosed, but is rather intended to cover any changes, adaptations or modifications which are within the scope and spirit of the invention as defined by the appended claims.

What is claimed is:

1. A logic circuit comprising:
a first input circuit coupled to receive a first input signal;
a second input circuit coupled to receive a second input signal;
wherein the first input circuit and the second input circuit are configured to provide symmetric loading of the first input signal and the second input signal; and
an output circuit configured to generate an output signal;
wherein at least one of the first input circuit, the second input circuit and the output circuit is configured to generate rising and falling edges of signals using the same type of transistor.

2. The logic circuit of claim 1 wherein the first input circuit and the second input circuit are configured to couple the same number of transistors to the first input signal and the second input signal, respectively.

3. The logic circuit of claim 1 wherein the first input circuit and the second input circuit are configured to couple the same types of transistors to the first input signal and the second input signal, respectively.

4. The logic circuit of claim 1 wherein the first input circuit and the second input circuit are configured to couple the first input signal and the second input signal, respectively, to substantially similar signal paths.

5. The logic circuit of claim 1 wherein the logic circuit generates the rising and falling edges using NMOS transistors.

6. The logic circuit of claim 1 comprising dummy circuits for loading the input signals.

7. The logic circuit of claim 1 comprising dummy circuits for loading the output signals.

8. The logic circuit of claim 1 wherein the logic circuit is configured to perform a least one of AND, NAND, OR, NOR and XOR logic operations.

9. A method of performing a logic operation comprising:
receiving input signals;
providing symmetric loading for the input signals;
generating rising and falling edges of signals using the same type of transistors;
providing symmetric loading for output signals; and
providing the output signals.

10. The method of claim 9 wherein the providing symmetric loading comprises coupling each input signal to the same number of components.

11. The method of claim 9 wherein the providing symmetric loading comprises coupling each input signal to the same type of components.

12. The method of claim 9 wherein the providing symmetric loading comprises providing substantially similar signal paths for each input signal.

13. The method of claim 9 wherein the generating rising and falling edges of signals comprises using NMOS transistors.

14. The method of claim 9 wherein the logic operation comprises AND, NAND, OR, NOR or XOR logic operations.

15. A logic circuit comprising:
a first differential transistor pair coupled to a first input terminal to receive a first differential input signal and coupled to an output terminal to generate a differential output signal;
a second differential transistor pair coupled to a second input terminal to receive a second differential input signal and coupled to the output terminal to generate the differential output signal;
a third differential transistor pair coupled to the output terminal to generate the differential output signal;
a fourth differential transistor pair coupled to the output terminal to generate the differential output signal;
a first bias transistor coupled to receive a first leg of the second input signal and coupled to provide a first bias signal to the first differential pair;
a second bias transistor coupled to receive a first leg of the first input signal and coupled to provide a second bias signal to the second differential pair;
a third bias transistor coupled to receive a second leg of the second input signal and coupled to provide a third bias signal to the third differential pair; and
a fourth bias transistor coupled to receive a second leg of the first input signal and coupled to provide a fourth bias signal to the fourth differential pair.

16. The logic circuit of claim 15 wherein inputs of the third differential pair are coupled to receive power supply signals.

17. The logic circuit of claim 15 wherein inputs of the fourth differential pair are coupled to receive power supply signals.

18. The logic circuit of claim 15 comprising a current source configured to provide the first bias signal, the second bias signal, the third bias signal and the fourth bias signal to the first bias transistor, the second bias transistor, the third bias transistor and the fourth bias transistor, respectively.

19. The logic circuit of claim 15 wherein the logic circuit is configured to perform a least one of AND, NAND, OR, NOR and XOR logic operations.
